(19) United States
(12) Patent Application Publication
(10) Pub. No.: US 2018/0233470 A1
(43) Pub. Date: Aug. 16, 2018

(54) HANDLING THIN WAFER DURING CHIP MANUFACTURE

(71) Applicant: Infineon Technologies AG, Neubiberg (DE)

(72) Inventors: Thomas Killer, Hohenschambach (DE); Markus Brunnbauer, Lappersdorf (DE); Marina Janker, Wenzenbach (DE); Adolf Koller, Regensburg (DE); Gabriel Maier, Regensburg (DE); Andreas Mueller-Hipper, Regensburg (DE); Andreas Stueckjuergen, Regensburg (DE); Christine Thoms, Zeitlarn (DE)

(73) Assignee: Infineon Technologies AG, Neubiberg (DE)

(21) Appl. No.: 15/897,654

(22) Filed: Feb. 15, 2018

(30) Foreign Application Priority Data
Feb. 15, 2017 (DE) 10 2017 103 095.6

(51) Int. Cl. H01L 23/00; H01L 21/3065; H01L 21/683; H01L 21/78; H01L 23/544

(52) U.S. Cl. CPC H01L 24/11; H01L 24/94; H01L 24/14; H01L 2224/023; H01L 21/6836; H01L 21/78; H01L 23/544; H01L 21/3065

(57) ABSTRACT

A manufacturing method is provided which comprises forming recesses in a front side of a wafer, connecting a first temporary holding body to the front side of the recessed wafer, thereafter thinning the wafer from a back side, connecting a second temporary holding body to the back side, and thereafter removing the first temporary holding body.

### CROSS-REFERENCE TO RELATED APPLICATION

This Utility Patent Application claims priority to German Patent Application No. 10 2017 103 095.6, filed Feb. 15, 2017, which is incorporated herein by reference.

### BACKGROUND OF THE INVENTION

### Field of the Invention

The present invention relates to manufacturing methods, an intermediate product, a semiconductor device, and an electronic device.

### Description of the Related Art

Conventional packages, such as mold structures, for electronic chips have evolved to a level where the package no longer significantly impedes the performance of the electronic chips. Moreover, processing electronic chips on wafer level is a known procedure for efficiently producing them. Etching electronic chips is a conventional technique for removing material therefrom. Encapsulating electronic chips during package manufacture may protect them against the environment.

In another technology, non-encapsulated semiconductor devices are used in which a redistribution layer together with solder structures are formed on a semiconductor body having an integrated circuit therein.

However, there is still potentially room to reduce manufacturing cost and simplify processing of electronic chips while maintaining a high accuracy of the processing. Moreover, it becomes more and more challenging to handle thinner and thinner wafers and electronic chips.

### SUMMARY

There may be a need for a reliable method of manufacturing electronic chips with small thickness.

According to an exemplary embodiment, a manufacturing method is provided which comprises forming recesses in a front side of a wafer, connecting a first temporary holding body to the front side of the recessed wafer, thereafter thinning the wafer from a back side, connecting a second temporary holding body to the back side, and thereafter removing the first temporary holding body.

According to another exemplary embodiment, a manufacturing method is provided which comprises forming recesses in a front side of a wafer, attaching electrically conductive interconnect structures on the front side of the wafer, connecting a first temporary holding body to the front side of the recessed wafer and embedding the electrically conductive interconnect structures in the first temporary holding body, and thereafter singularizing the wafer into a plurality of electronic chips.

According to still another exemplary embodiment, a manufacturing method is provided which comprises forming a recess in a front side of a wafer, connecting a temporary holding body to the front side of the recessed wafer, and thereafter thinning the wafer from a back side up to a thickness of less than 300 μm.

According to yet another exemplary embodiment, an intermediate product is provided which comprises a plurality of electronic chips, at least one solder structure on each of the electronic chips, and a common temporary holding body on the electronic chips and the electrically conductive interconnect structures.

According to yet another exemplary embodiment, a non-encapsulated semiconductor device is provided which comprises a semiconductor body having a thickness of not more than 200 μm, at least one solder structure on a front side of the semiconductor body, and a redistribution layer between the semiconductor body and the at least one solder structure.

According to still another exemplary embodiment, an electronic device is provided which comprises a device carrier (for example a printed circuit board, PCB) and a non-encapsulated semiconductor device having the above-mentioned features and being mounted on the device carrier.

According to an exemplary embodiment of the invention, a method of manufacturing semiconductor devices is provided in which a wafer is first recessed from a front side and is then thinned from a back side after having connected the wafer to a first temporary holding body. After this thinning, which may also accomplish singularization of the electronic chips of the wafer, a second temporary holding body may be attached to the back side (at which thinning has occurred), and the first temporary holding body may then be removed. Alternatively, singularization may also be achieved by front side cutting after back side thinning. By such an architecture, it can be accomplished that the sensitive thinned electronic chips and/or wafer remain(s) always attached to at least one temporary holding body, which significantly simplifies handling and protects the thin electronic chips or the thin wafer from damage. Thus, the described architecture allows to manufacture (in particular non-encapsulated or naked) semiconductor devices with significantly thinner thicknesses as can be achieved conventionally. Therefore, the manufacturing architecture promotes miniaturization of electronic chips without increasing the risk of damage of the sensitive thin electronic chips.

### DESCRIPTION OF FURTHER EXEMPLARY EMBODIMENTS

In the context of the present application, the term “temporary holding body” may particularly denote a body (such as a flexible foil) which temporarily holds a wafer and/or individual electronic chips during manufacturing semiconductor devices, but does not form part of the readily manufactured semiconductor devices. Thus, the one or more temporary holding bodies (which may also denoted as temporary carrier in certain embodiments) may be removed from the wafer or the electronic chips after temporary adhesion thereon. The temporary holding body/bodies may hold or support wafer or chips and may therefore simplify their handling, especially when wafer or chips are already very thin. A deformable temporary carrier may also cover a surface of wafer or chips and may therefore protect the latter from chemical or mechanical impact during processing, for instance during grinding.

In the context of the present application, the term “non-encapsulated semiconductor device” may particularly denote a semiconductor chip in which a semiconductor chip (i.e. a naked die in which at least one monolithically integrated circuit can be formed) is provided with an electric coupling structure (such as a redistribution layer), but is not encapsulated by a mold compound, a laminate, or another encapsulant. However, the non-encapsulated semiconductor device may be covered with a layer of varnish or the like (which may be applied for instance by spraying after singularization). It is also possible that the non-encapsulated semiconductor device is covered with a (for instance black) backside protection foil (BSP foil).

In the following, further exemplary embodiments of the methods, the intermediate product, the semiconductor device, and the electronic device will be explained.

In an embodiment, the method may be configured to operate in accordance with a Wafer Level Ball Grid Array architecture applied to a Chip-Scale-Package.

In an embodiment, the method comprises removing material of the recessed wafer from at least one of the front side and the back side to thereby singularize the wafer into a plurality of electronic chips. In one embodiment, singularization is accomplished by removing material only from the back side of the wafer by grinding (see for instance FIG. 1 to FIG. 7). In another embodiment, singularization is carried out by firstly removing material from a back side of a wafer by grinding, followed by blade dicing of a previously formed recess on the front side (see for instance FIG. 8 to FIG. 13). Both procedures allow to manufacture semiconductor devices with extremely thin thickness without handling issues.

In an embodiment, the method comprises removing the material by at least one of the group consisting of grinding from the back side, and cutting with a blade from the front side. With a grinding procedure, a homogeneous thinning of the wafer can be accomplished. By cutting with a blade (which may also be denoted as blade dicing), pre-cut recesses of a groove type may be converted into through holes, thereby completing the singularization procedure. These recesses may be channels or oblong holes.

In an embodiment, the one or more recesses are formed by plasma treatment or laser grooving. The recessing may include the formation of trenches separating regions of the processed wafer which regions later constitute the individual semiconductor devices or electronic chips. Forming such trenches or grooves, which may later define separation positions when thinning, may be accomplished advantageously by plasma treatment. A specific further advantage of plasma etching is that this allows to freely select chip shapes (for instance rectangular, circular, octagonal, etc.). Contrary to mechanical recess formation techniques, plasma treatment is very gentle for the already thin wafer which provides a reliable protection against breakage or deterioration of the wafer or electronic chips. However, other recess forming techniques are possible as well (for instance blade dicing) as long as it is ensured that recess formation does not damage the wafer material. When a laser is guided along a surface of the wafer, the recess(es) may also be formed by such a laser processing or laser ablation.

In an embodiment, the thinning is carried out by grinding. Grinding may be accomplished mechanically and may remove material of the wafer from the back side so that the correspondingly formed electronic chips may be singularized (or singularization may be prepared) when the grinding procedure reaches (or approaches) the recesses formed from the front side. As an alternative to thinning by grinding, it is also possible to thin the wafer by plasma treatment, chemical etching, laser processing, etc.

In an embodiment, the method further comprises attaching electrically conductive interconnect structures on the front side of the wafer (or onto a redistribution layer on the wafer) before connecting the first temporary holding body to the front side of the recessed wafer and to the electrically conductive interconnect structures. Preferably, the electrically conductive interconnect structures may be solder structures, more particularly solder balls, which may be soldered onto the front side of the wafer. However, as an alternative to solder balls or the like, it is also possible to configure the electrically conductive interconnect structures as bumps. In such an embodiment, an electrically conductive material (in particular copper) may be grown (for instance with a thickness in a range between 10 μm and 50 μm) and may be covered by a non-oxidizing layer (for instance having a thickness of several micrometers, for example an electroless NiPPd layer). Also this allows soldering on a PCB (printed circuit board) or another device carrier. Moreover, the electrically conductive interconnect structure may be configured for an electrically conductive interconnection by soldering or another electrically contacting method. Such alternatives may be the use of electrically conductive adhesive, adhesive becoming electrically conductive by applying pressure, etc.

The wafer and its electronic chips may be processed by semiconductor technology on the front side. In other words, one or more integrated circuit elements may be monolithically integrated in an active region on the front side of the wafer and its electronic chips. Correspondingly, a redistribution layer (translating between the small dimensions of the semiconductor world and the larger dimensions of the PCB world) may be formed on the front side. Electrically coupling the readily formed semiconductor device or electronic chip with an electronic environment such as a printed circuit board can be accomplished by the electrically conductive interconnect structures applied on the front surface of the wafer or electronic chips. Surprisingly, the provision of solder balls or any other electrically conductive interconnect structures on the front side and resulting in the formation of a surface profile or protrusions does not prevent such a structure from being properly connected to the first temporary holding body. On the contrary, it is possible to embed the electrically conductive interconnect structures in the first temporary holding body before grinding for planarizing and protection purposes.

In an embodiment, the method further comprises at least one of the group consisting of carrying out a function test of the wafer and writing data in the wafer. This can be accomplished by applying an electric signal to the electrically conductive interconnect structures before connecting the first temporary holding body to the front side of the recessed wafer and to the electrically conductive interconnect structures. Additionally or alternatively to the execution of the functional test, it is also possible that a wafer probe or the like is used for writing data in the wafer or the electronic chips thereof. For instance, such data may be parameters for trimming or linearizing the function of the respective electronic chip, a loading of an operation system or other software in a memory of the respective electronic chip, etc. In a cryptographic application, it is for instance possible to write a chip individual key into a respective electronic chip which thereby can become unique.

The entire electronic functionality is already provided by the electronic chips or the semiconductor devices while still being interconnected on wafer level prior to singularization. Therefore, it is possible to carry out an electronic functional test by applying a stimulus signal to the electrically conductive interconnect structures and measuring a response signal on the same and/or other electrically conductive interconnect structures prior to the singularization.

In an embodiment, the method further comprises laser processing the back side (in particular of the already singularized wafer, or of the wafer before completing singularization) through the second temporary holding body. For instance, the electronic chips or wafer may be provided with an identifier which can be engraved on the functionally inactive back side of the electronic chips or wafer by laser processing. Advantageously, it is not necessary to remove the second temporary holding body for laser marking, because it has turned out that the laser radiation can go through the second temporary holding body substantially without absorption of the laser radiation by the second temporary holding body when the laser wavelength (for instance green light) and the material (for instance a suitable polymer) of the second temporary holding body are adjusted correspondingly.

In an embodiment, the method further comprises picking the electronic chips individually from the second temporary holding body. When the first temporary holding body has been removed, it is possible that the individual electronic chips or semiconductor devices are individually picked by a pick-and-place mechanism and are either directly assembled onto a device carrier (such as a PCB) or are mounted on a tape (for instance in a tape-and-reel procedure) or the like. For instance, such a tape being equipped with the individual electronic chips of thin size may then be rolled on a roll. For instance, the individual electronic chips may be picked by a suction mechanism detaching the electronic chips from the second temporary holding body with vacuum force.

In particular, the described picking procedure may be accomplished by a suction cannula sucking (in particular supported by a vacuum) a front side of a respective one of the electronic chips or semiconductor devices while a release body (such as a release needle) pushes the respective one of the electronic chips from a back side thereof (in particular through the second temporary holding body).

In an embodiment, the method further comprises connecting the second temporary holding body to the back side before removing the first temporary holding body. By connecting the second temporary holding body to the semifinished product prior to removing the first temporary holding body, it is ensured that the sensitive thin electronic chips or wafer are/is never separate from at least one of the temporary holding body. Thus, damage of the sensitive thinned electronic chips or wafer may be safely prevented by the provision of two temporary holding bodies, one to be attached to the front side and the other one to be attached to the back side.

In an embodiment, the method comprises singularizing the wafer into the plurality of electronic chips by thinning the wafer from a back side at least up to the recesses. Such an embodiment is described referring to FIG. 1 to FIG. 7. The grinding procedure is continued until the grinding reaches the recesses on an opposing main surface of the wafer, thereby completing singularization.

In another embodiment, the method comprises singularizing the wafer into the plurality of electronic chips by thinning the wafer from a back side followed by a removal of material at the recesses from the front side. In such an alternative embodiment, see for instance FIG. 8 to FIG. 13, the singularization is not yet completed after grinding. In contrast to this, after the grinding, cutting with a blade is carried out for completing singularization, i.e. cutting of the preformed recesses of the thinned wafer until the individual electronic chips are separated.

In an embodiment, the first temporary holding body is configured as a flexible (for instance adhesive) sheet with a plastically deformable or deformed surface portion facing the at least one solder structure. For instance, the first temporary holding body may be a flexible foil which can be attached (for instance by lamination) onto the upper surface of the wafer. The foil may have a carrier film on which deformable material may be applied. By thermal treatment, the first temporary holding body may start melting and may be plastically deformed so as to form a substantially inverse surface profile than the surface of the wafer with electrically conductive interconnect structures thereon. By taking this measure, the electrically conductive interconnect structures are embedded in the first temporary holding body in a way that a later release of the first temporary holding body from the then singularized electronic chips may be carried out without damage of the electrically conductive interconnect structures. The first temporary holding body may cover the electrically conductive interconnect structures like a tent. The first temporary holding body may also serve as a surface protection and may have a planarizing effect of the wafer or electronic chips. In another embodiment, the first temporary holding body may be made based on a flowable medium (such as a polymer liquid or viscous material) which can be applied (for instance dispensed) in liquid form and cured (for instance thermally) thereafter on the upper surface of the wafer.

In an embodiment, the second temporary holding body is configured as a flexible (for instance adhesive) sheet. Thus, the second temporary holding body may be a flexible foil which can be attached (for instance by lamination) onto the lower surface of the wafer or of the already separated electronic chips. In another embodiment, the second temporary holding body may be a flowable medium (such as a polymer liquid or viscous material) which can be applied (for instance dispensed) and cured (for instance thermally) on the lower surface of the wafer or the already separated electronic chips. The second temporary holding body may also serve as a support, a surface protection and may have a planarizing effect.

In an embodiment, the method further comprises laser marking the back side while the electronic chips remain attached to the second temporary holding body. Astonishingly, laser marking is possible on the back side of the thinned electronic chips through the second temporary holding body, so there is no need for removing the electronic chips for marking. Alternatively, device marking for traceability may also be done by laser processing after having detached individual semiconductor devices from the second temporary holding body.

In an embodiment, the method further comprises individually, i.e. one-by-one, detaching the electronic chips from the second temporary holding body. The electronic chips may therefore be removed one after the other from the second temporary holding body for further processing, for instance assembling or transfer to a tape.

In an embodiment, the wafer is thinned from an initial thickness of at least 600 μm to a final thickness of not more than 200 μm. At a thickness of 600 μm or more, it is still possible to handle the wafer separately without severe risk of damage. For instance, the initial thickness may be even larger than 700 μm. By the thinning procedure, the thickness may be reduced up to not more than 200 μm, in particular even 150 μm or less. This procedure is strongly supported by the use of two temporary holding bodies ensuring that at no time the thinned electronic chips need to be handled independently of a holding body. Thereby, damage of the extremely thin electronic chips may be safely prevented.

In an embodiment, the method further comprises re-adhering the electronic chips from the first temporary holding body to the second temporary holding body on the back side. In other words, the thinned electronic chips may be first attached on their front side with the first temporary holding body and may then be connected on their back side with a second temporary holding body, preferably before the first temporary holding body is removed. Thereby, the adhering main surface (i.e. front side or back side) of the electronic chips may be changed after thinning and before picking the electronic chips.

In an embodiment, the method further comprises soldering electrically conductive interconnect structures on the front side of the wafer before the thinning. This renders it unnecessary or dispensable that the already thinned or even separated chips are made subject of a solder application process. In contrast to this, solder application may already be accomplished prior to thinning and therefore on a still integral wafer. This relaxes the requirements in terms of registration accuracy.

In an embodiment, the electrically conductive interconnect structures are embedded at least partially in the temporary holding body. They may be embedded sufficiently loose so that the electrically conductive interconnect structures remain attached on the electronic chips upon detaching the temporary holding body from the electronic chips. By the embedding of the protruding electrically conductive interconnect structures (which may involve a deformation of a foil-type first temporary holding body), the contact between the first temporary holding body and the constituents on the front side of the wafer with redistribution layer and electrically conductive interconnect structures thereon may be rendered reliable. The solder balls protruding beyond the rest of the surface of the electronic chips may therefore be temporarily placed in an interior of the first temporary holding body. This can for instance be accomplished by a sufficiently soft and/or deformable first temporary holding body or by a temporary holding body having permanent recesses at the positions of the electrically conductive interconnect structures. By both methods it can be ensured that a planar structure is obtained by the wafer with electrically conductive interconnect structures and first temporary holding body attached thereto, which simplifies grinding.

In an embodiment, the electronic chips of the intermediate product have a thickness of not more than 200 μm. Correspondingly, the semiconductor body of the semiconductor device may have a thickness of not more than 200 μm. Therefore, the electronic chips may be made remarkably thin after grinding without handling issues. Hence, their handling is unproblematic since they always remain attached to at least one of the temporary holding bodies prior to being picked and transported to a destination.

In an embodiment, the semiconductor device is configured as a Chip-Scale-Package (CSP package). In order to qualify as chip scale, the package should have an area no greater than 1.2 times that of the die or electronic chip and it shall be a single-die, direct surface mountable package. Another criterion that may be applied to qualify a package as a CSP package is its ball pitch should be no more than 1 mm. In particular, a CSP package may have a dimension which is not more than 20% larger than a dimension of the electronic chip thereof. A CSP package is usually non-encapsulated and can therefore be provided with a very small thickness. Consequently, a CSP package is highly appropriate for applications such as wearables, portable devices, watches, smart glasses, etc.

In a preferred embodiment, the electronic chip is configured as a controller chip, a processor chip, a memory chip, a sensor chip or a micro-electromechanical system (MEMS),In an alternative embodiment, it is also possible that the electronic chip is configured as a power semiconductor chip. Thus, the electronic chip (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide, gallium nitride or gallium nitride on silicon). A semiconductor power chip may comprise one or more field effect transistors, diodes, inverter circuits, half-bridges, full-bridges, drivers, logic circuits, further devices, etc.

In one embodiment, the device carrier may be configured as a printed circuit board (PCB). However, other kinds of device carriers may be used as well. For example, the semiconductor devices may also be mounted on and/or in other device carriers such as a chip card. Such a chip card may for example comprise a chip or semiconductor device and an antenna, etc.

As substrate or wafer forming the basis of the electronic chips, a semiconductor substrate, preferably a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology. A semiconductor device according to an exemplary embodiment may be configured as micro-electromechanical system (MEMS), sensor, etc.

Furthermore, exemplary embodiments may make use of standard semiconductor processing technologies such as appropriate etching technologies (including isotropic and anisotropic etching technologies, particularly plasma etching, dry etching, wet etching), patterning technologies (which may involve lithographic masks), deposition technologies (such as chemical vapor deposition (CVD), plasma enhanced chemical vapor deposition (PECVD), atomic layer deposition (ALD), sputtering, etc.).

The above and other objects, features and advantages of the present invention will become apparent from the following description and the appended claims, taken in conjunction with the accompanying drawings, in which like parts or elements are denoted by like reference numbers.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 to FIG. 7 show cross-sectional views of intermediate products obtained during carrying out a method of manufacturing a semiconductor device according to an exemplary embodiment.

FIG. 8 to FIG. 13 show cross-sectional views of intermediate products obtained during carrying out a method of manufacturing a semiconductor device according to another exemplary embodiment.

FIG. 14 shows a cross-sectional view of an electronic device composed of a Chip-Scale-Package, as a surface mounted semiconductor device, and a printed circuit board (PCB), as a device carrier for the semiconductor device, according to an exemplary embodiment.

### DETAILED DESCRIPTION OF EXEMPLARY EMBODIMENTS

The illustration in the drawing is schematically.

Before describing further exemplary embodiments in further detail, some basic considerations of the present inventors will be summarized based on which exemplary embodiments have been developed which provide for a manufacturing concept capable of handling very thin wafers and electronic chips.

According to an exemplary embodiment of the invention, a process flow for manufacturing semiconductor devices by a modified Wafer Level Bonding architecture is provided. More specifically, an exemplary embodiment provides a semiconductor package with a small thickness of its semiconductor material (in particular silicon material) as package body. In particular, such a manufacturing architecture is in particular advantageous for a chip scale package concept.

In conventional approaches, a Chip-Scale-Package manufacturing procedure requires a certain minimum thickness of the wafer so that it can be handled during processing. At present, wafers need to have a minimum thickness of 400 μm in order to be processable with standard handling equipment. Special equipment capable of handling very thin wafers may then be dispensable.

In contrast to this, an exemplary embodiment of the invention is compatible with even significantly smaller thicknesses of semiconductor material. When the wafer has been processed, i.e. integrated circuit (IC) elements have been monolithically integrated therein and a redistribution layer has been formed thereon, plasma dicing (i.e. forming recesses by plasma treatment) may be initiated. Alternatively, also blade dicing (i.e. forming recesses by a mechanical cutting procedure using a blade) can be carried out. With such a procedure, recesses may be formed in a front side surface of the wafer.

Subsequently, it is possible that electrically conductive interconnect structures (in particular solder balls) are soldered onto the front surface of the wafer, more precisely on the redistribution layer thereof. At this stage of the manufacturing procedure, an electric test of the functionality of the electronic chips, which are still connected to one another on wafer level, can be carried out using the electrically conductive interconnect structures.

Subsequently, the individual electronic chips, members or semiconductor devices may be singularized by grinding of the wafer from a back side. During this procedure, it is possible that the electrically conductive interconnect structures previously applied are embedded within a first temporary holding body which may also be denoted as a grinding foil.

The singularized electronic chips, which are separated at the positions of the previously formed recesses as a consequence of the grinding, can then be re-adhered from the grinding foil onto another foil (which may be a sawing foil and which may be denoted as second temporary holding body). This means that the second temporary holding body may be adhered to the back side of the singularized electronic chips, and thereafter the first temporary holding body may be removed. By taking this measure, the thin singularized electronic chips are never handled separately from at least one of the temporary holding body foils. This significantly simplifies handling and prevents damage of the sensitive very thin electronic chips. Thus, the grinded back side is now attached to the second temporary holding body which can be a sticky foil.

Subsequently, the back side may be made subject of a laser marking procedure through the second temporary holding body. This means that the laser may propagate through the second temporary holding body and may engrave or mark a back side of the electronic chips.

Next, the individual electronic chips adhering to the second temporary holding body may be picked from the second temporary holding body and may be further processed later. For example, they can be attached on a belt or band or tape.

The described process flow has significant advantages. With such a procedure, the electronic chips, which are at the beginning still an integral part of a wafer compound, may remain on a relatively large start thickness (for instance 775 μm) until they are grinded back onto their final smaller thickness (for instance about 150 μm). This simplifies handling and protects the electronic chips against damage. When grinding the wafer, the electronic chips are simultaneously singularized. This can be denoted as “dice before grind”.

The described manufacturing architecture has the advantage that CSP packages with a very small thickness of for example 100 μm may be obtained without the risk that the chips are destroyed during the manufacturing process. A thin foil may be used as a respective holding body.

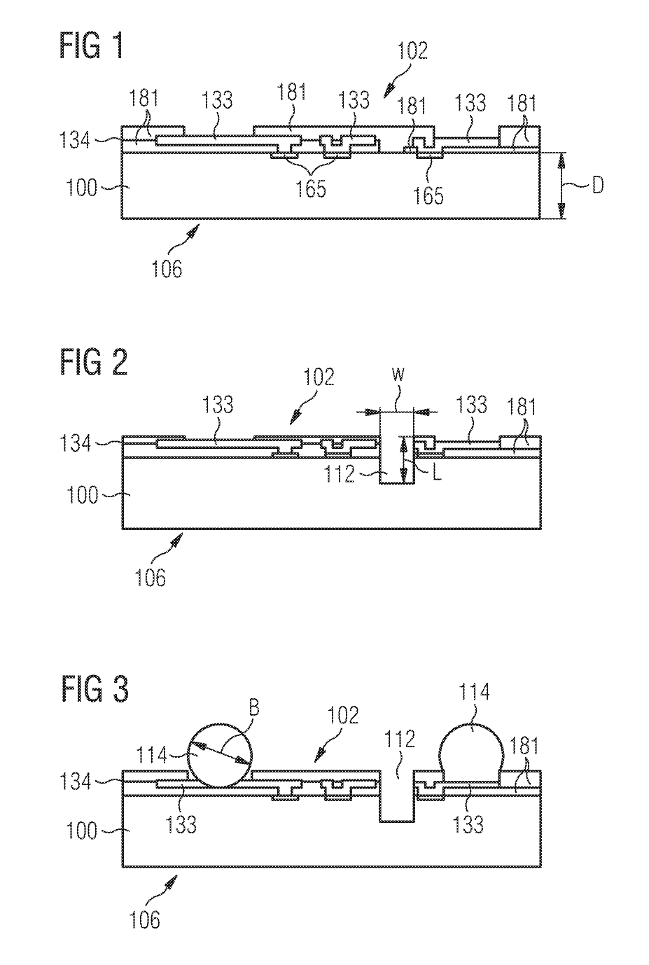

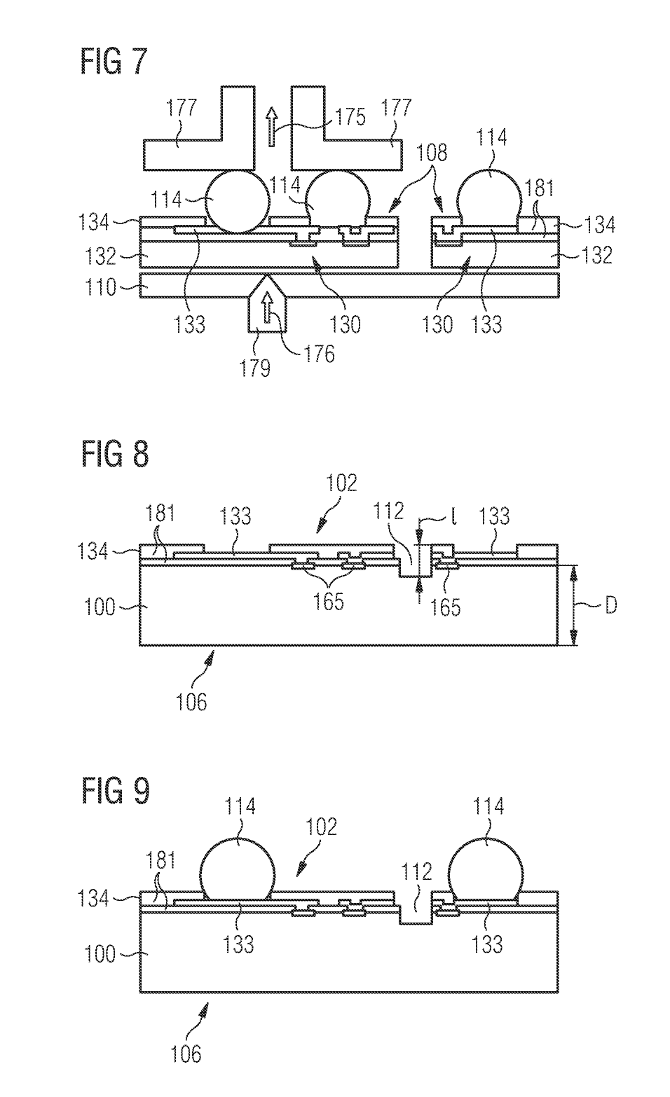

FIG. 1 to FIG. 7 show cross-sectional views of intermediate products obtained during carrying out a method of manufacturing semiconductor devices 130 according to an exemplary embodiment. The manufactured semiconductor devices 130 are shown in FIG. 6 and FIG. 7. The described procedure refers to a manufacturing stage after completion of the semiconductor processing and before assembling the non-encapsulated semiconductor devices 130 on a device carrier 192 such as a PCB (see FIG. 14).

FIG. 1 shows a semiconductor wafer 100, here embodied as a silicon wafer, having a front side 102 and a back side 106. The wafer 100 may be a circular disk having for instance a diameter of 300 mm and may have an initial thickness, D, of for example 775 μm. It should however be said that other dimensions are possible as well. For instance, the diameter of the wafer 100 may also be 200 mm, 400 mm or 450 mm. On the front side 102, a plurality of integrated circuit elements (such as transistors, diodes, etc.) are monolithically integrated in the surface portion of the wafer 100. The front side 102 corresponds to an active region of the wafer 100. On a surface of the front side 102 of the wafer 100, chip pads 165 are formed. The wafer 100 includes multiple electronic chips 108 which may be controllers, processors, memory chips, sensors or semiconductor power chips. The electronic chips 108 are still integrally connected according to FIG. 1. In contrast to this, the back side 106 of the wafer 100 has not been processed by semiconductor technology in the shown embodiment.

After having monolithically integrated the integrated circuit elements in the active region on the front side 102 of the wafer 100, a redistribution layer 134 is formed on the front side 102. The redistribution layer 134 serves as an interface for increasing pitch. The redistribution layer 134 is configured as a layer sequence comprising one or more dielectric layers 181 (in particular made of polyimide) in which metallic structures 133 (for instance galvanic copper or aluminium) are embedded. The metallic structures 133 are exposed for being connectable to electrically conductive interconnect structures 114, i.e. for defining positions of the electrically conductive interconnect structures 114 (see FIG. 3). The metallic structures 133 are also electrically coupled with the chip pads 165 on the active region in an upper portion of the wafer 100. The redistribution layer 134 thereby translates between the small distances of structures in the semiconductor world, i.e. of the monolithically integrated circuit elements on the front side 102 of the wafer 100, to larger dimensions of a device carrier 192 on which the electronic chips 108 to be singularized from the wafer 100 may be mounted. For example, such a device carrier 192 may be a printed circuit board (PCB) or a chip card.

Referring to FIG. 2, one or more recesses 112 are formed in a surface portion on the front side 102 of the wafer 100 by plasma treatment or etching fluid or by laser-ablation. When implementing etching fluid, formation of the recesses 112 can be accomplished using a liquid etch medium resulting in an isotropic etching process. When however the crystal orientation of the silicon material is selected properly, this process is nevertheless capable of etching up to a predefined depth. The process of forming the recesses 112 can be called cut-in. For this purpose, a mask (not shown) may be applied on the redistribution layer 134 and may be provided with openings for defining the kerv, i.e. the positions and dimensions of the recesses 112. Thereafter, it is possible to carry out one or more isotropic and/or anisotropic etching procedures, which may involve a plasma. This allows to define the recesses 112 highly precisely in terms of position, depth, and shape (i.e. trench-like with substantially rectangular cross section). In the described embodiment, a depth, L, of the recesses 112 may be slightly larger than a final thickness of the semiconductor devices 130 under manufacture (compare FIG. 7). For instance, the depth, L, may be in a range between 100 μm and 200 μm in the described embodiment. Also a width, w, of the recesses 112 may be very small. As a result of the described manufacturing method, a small kerv is obtained. Width w may for instance be in a range between 30 μm and 70 μm, for example 54 μm. When using plasma etching, recesses 112 with a very small width, w, can be formed (for instance in a range between some micrometers, in particular 5 μm, and 70 μm). This allows to obtain a larger number of electronic chips 108 from a wafer 100, since less semiconductor material is lost.

Hence, in order to obtain the structure shown in FIG. 2, a plasma cutting (or plasma dicing) procedure is carried out for forming the recesses 112 on the front side 102. This can be accomplished by a plasma treatment, i.e. in a very gentle and nevertheless reliable and reproducible way. By this recessing procedure, the borders between adjacent electronic chips 108 (see FIG. 5) to be singularized are precisely defined. This procedure may also be called plasma pre-cut.

Referring to FIG. 3, electrically conductive interconnect structures 114, here embodied as solder balls, may be soldered on the front side 102 of the wafer 100, more particularly on the metallic structures 133 thereof. A diameter, B, of the here ball-shaped electrically conductive interconnect structures 114 may for instance be 190 μm. Soldering the electrically conductive interconnect structures 114 on the metallic structures 133 may involve a temperature of for instance 260° C. Thus, soldering the electrically conductive interconnect structures 114 already at the present stage of the process on the metallic structures 133 protects later attached foil-type temporary holding bodies 104, 110 (see FIG. 5 and FIG. 6) from thermal damage. Thus, the freedom of design of selecting materials for temporary holding bodies 104, 110 is increased, since their material need not necessarily be temperature-stable up to solder temperatures. It is also much more simple to attach electrically conductive interconnect structures 114 to the metallic structures 114 as long as the wafer 100 is still integral and not yet singularized into electronic chips 108 (for instance in terms of registration accuracy).

In order to obtain the structure shown in FIG. 3, the electrically conductive interconnect structures 114 are connected to the redistribution layer 134 by soldering. The solder balls 114 accomplish a solder connection between the electronic chips 108 to be singularized from the wafer 100 on the one hand and the device carrier 192 (for instance a PCB, not shown) on the other hand. The procedure of soldering the electrically conductive interconnect structures 114 onto the redistribution layer 132 may also be called ball apply.

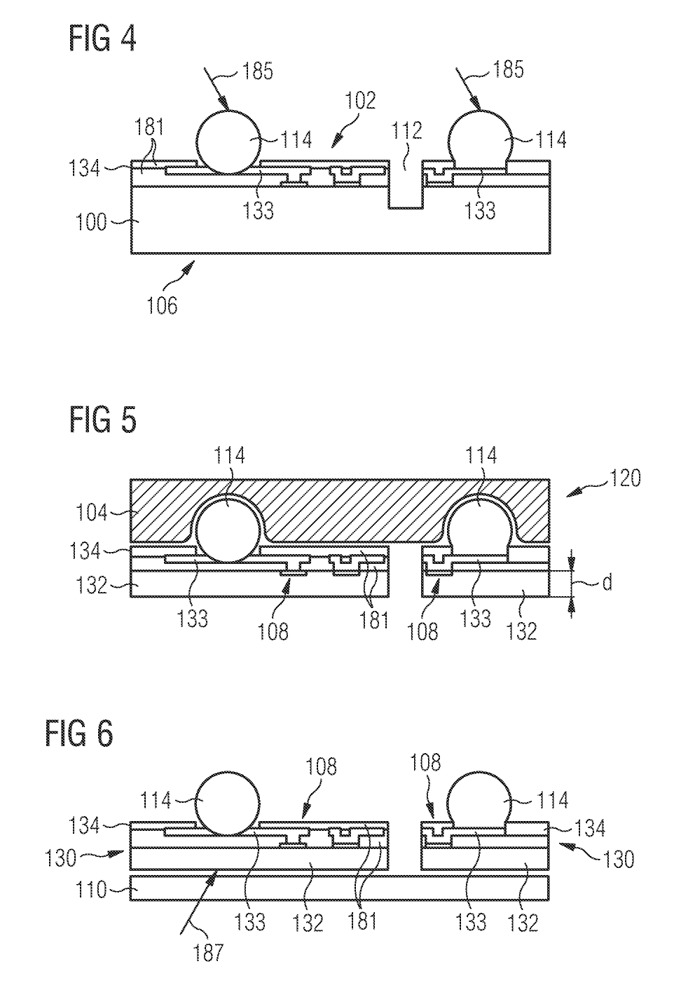

Referring to FIG. 4, the method further comprises carrying out an electronic function test by applying an electric signal to the electrically conductive interconnect structures 114. As can be taken from FIG. 4, and as indicated there schematically by arrows 185, an electric test of the function of the electronic chips 108 to be singularized from the wafer 100 can be carried out. With the function test, it may be tested whether the wafer 100 has suffered damage during the procedures according to FIG. 1 to FIG. 3. Needles of a needle array (or needle cartridge) of a test device (not shown) may contact the electrically conductive interconnect structures 114 for testing purpose. An electric stimulus may be applied and an electric response signal may be measured, leak tests may be executed, etc. The same test device may be used for the described function test which has also been used for a front end test, thereby further increasing efficiency of the process. Apart from such a function test, it is also possible to write data in the wafer 100 or in the individual electronic chips 108 by means of the test device.

Referring to FIG. 5, a flexible and deformable first temporary holding body 104 is connected to the front side 102 of the recessed wafer 100 and to the electrically conductive interconnect structures 114. Thus, the electrically conductive interconnect structures 114 are formed on the redistribution layer 132 and the electronic test (see FIG. 4) is carried out before attaching the first temporary holding body 104. Thereafter, the wafer 100 may be made subject of a thinning procedure for thinning the wafer 100 from a back side 106 up to a thickness, d, of less than 300 μm to thereby singularize the wafer 100 into the plurality of electronic chips 108. During this thinning procedure by grinding, the wafer 100 is thinned from initial thickness, D, of at least 600 μm to a final thickness, d, of for instance 150 μm. The thinning by grinding is continued until it reaches the bottom surface of the recesses 112, thereby separating or singularising the multiple individual electronic chips 108 from the previously integral wafer 100.

The first temporary holding body 104 is attached to the front side 102 of the recessed wafer 100 by lamination in such a way that the electrically conductive interconnect structures 114 and the redistribution layer 134 are thereby covered by the first temporary holding body 104. The planar surface of the redistribution layer 134 is covered by the first temporary holding body 104 in a liquid tight way, and the electrically conductive interconnect structures 114 are covered by the first temporary holding body 104 like a tent. This coverage prevents the electrically conductive interconnect structures 114 and the redistribution layer 134 as well as the semiconductor structures beneath from damage during grinding. The grinding procedure may generate abrasive slurry which can contaminate or even damage electrically conductive interconnect structures 114 and the integrated circuit elements of the wafer 100, i.e. its active region. Hence, damage may result from mechanical stress and/or from chemical impact of slurry. Advantageously, the temporary holding body 104 is configured as a flexible sheet with a plastically deformable or deformed surface portion facing the electrically conductive interconnect structures 114. By the application of heat and pressure, plastic deformation of the temporary holding body 104 can be triggered which embeds the electrically conductive interconnect structures 114 in accommodation volumes formed within the first temporary holding body 104. By this procedure, the first temporary holding body 104 is laminated onto the electrically conductive interconnect structures 114 and the redistribution layer 134.

As a result of the described procedure of laminating and grinding, intermediate product 120 as shown in FIG. 5 is obtained. The intermediate product 120 comprises the plurality of separated electronic chips 108 each being covered by a portion of the redistribution layer 134 and at least one of the electrically conductive interconnect structures 114. The first temporary holding body 104 remains attached to all now separated electronic chips 108 and the electrically conductive interconnect structures 114 in common and thereby simplifies handling the huge amount of thin and therefore sensitive electronic chips 108. In particular, the electrically conductive interconnect structures 114 are embedded in the temporary holding body 104 in a tent-like way. This only slight interaction between the first temporary holding body 104 and the electrically conductive interconnect structures 114 prevents damage of the electrically conductive interconnect structures 114 during later detachment of the first temporary holding body 104 (see FIG. 6).

As mentioned, the wafer 100 is singularized into the plurality of separate electronic chips 108 by release grinding of the wafer 100 from the back side 106. However, before initiating this grinding procedure, the front side of the structure shown in FIG. 4 is covered with first temporary holding body 104. As a result of this coverage, the electrically conductive interconnect structures 114 are embedded in the first temporary holding body 120 to obtain a planar structure which can be handled well. This renders the grinding process more accurate.

Referring to FIG. 6, the method continues with a procedure of re-adhering the electronic chips 108 from the first temporary holding body 104 on the front side 102 to a second temporary holding body 110 on the back side 106. More specifically, the second temporary holding body 110 is firstly connected to the back side 106 of the singularized wafer 100, i.e. the electronic chips 108, by lamination. The second temporary holding body 110 may be configured as a flexible sheet adhering to the back side 106. Thereafter, the first temporary holding body 104 can be removed or detached from the electronic chips 108, for instance by peeling it off. Thus, the second temporary holding body 110 is attached to the back side 106 before removing the first temporary holding body 104. This ensures that the sensitive thin and separate electronic chips 108 are supported continuously by at least one of the temporary holding bodies 104, 110 ensuring a protection and capability of handling them uninterruptedly.

As indicated schematically by reference numeral 187, the method further comprises laser processing the back side 106 of the electronic chips 108 of the singularized wafer 100 through the second temporary holding body 110. In other words, a marking is formed on the back side 106 of the electronic chips 108 by a laser which propagates through the second temporary holding body 110. For this purpose, a wavelength of the laser (for instance a laser which emits in the green wavelength range) may be selected so that the electromagnetic radiation emitted by this laser is substantially not absorbed by the material of the second temporary holding body 110. By taking this measure, laser marking the back side 106 can be accomplished while the electronic chips 108 remain attached to the second temporary holding body 110. Laser marking may be advantageous in terms of traceability of individual semiconductor devices 130 obtained as a consequence of the singularization of the wafer 100 into the electronic chips 108. Laser marking may be accomplished on a frame.

As a result of the described manufacturing procedure, the non-encapsulated (i.e. being free of a mold compound or a lamination encapsulation) semiconductor devices 130 with back side marking shown in FIG. 6 are obtained. The non-encapsulated semiconductor devices 130, configured as Chip-Scale-Packages (CSP packages) are composed of semiconductor bodies 132 having a thickness of 150 μm, electrically conductive interconnect structures 114 on front side 102 of the semiconductor body 132, and redistribution layer 134 between the semiconductor body 132 and the solder structure 114.

Referring to FIG. 7, the described manufacturing method further comprises individually detaching the semiconductor devices 130 from the second temporary holding body 110. More specifically, the semiconductor devices 130 (and consequently also the electronic chips 108) are individually picked from the second temporary holding body 110. This can be accomplished by a suction cannula 177 applying a sucking force 175 (generated by a vacuum) on a front side of a respective one of the semiconductor devices 130 while a release body 179 pushes the respective one of the electronic chips 108 upwardly from a back side thereof (see pushing force 176). Thus, a picking element, which is here embodied as suction cannula 177 is capable of individually picking the singularized semiconductor devices 130. In the shown embodiment, the picking element is hence a suction cup which can pick up a respective one of the semiconductor devices 130 by a vacuum force. The picked up semiconductor devices 130 or electronic chips 108 may then be made subject of a tape and reel procedure (not shown).

As an alternative to the described method, it is also possible to carry our laser marking for traceability purposes after having picked the individual semiconductor devices 130 according to FIG. 7 (rather than through the second temporary holding body 110 according to FIG. 6).

FIG. 8 to FIG. 13 show cross-sectional views of intermediate products obtained during carrying out a method of manufacturing semiconductor devices 130 according to another exemplary embodiment.

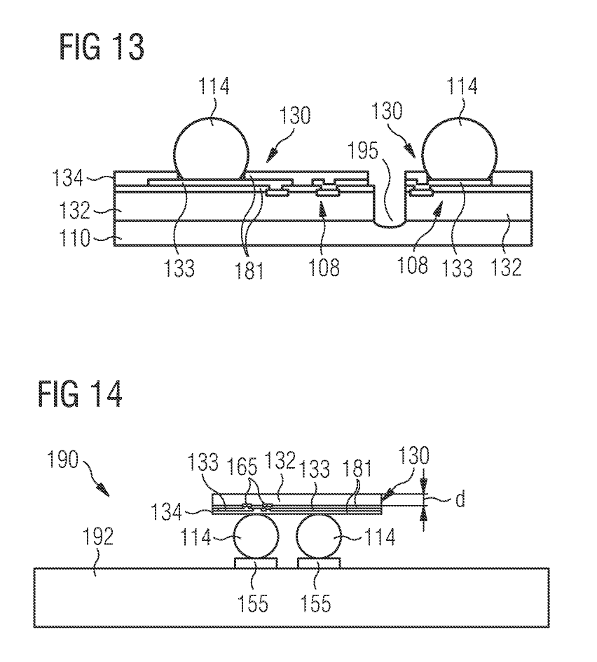

Referring to FIG. 8, recesses 112 are formed in a surface of a wafer 100 covered with redistribution layer 134 in a corresponding way as described above referring to FIG. 2. However, in the embodiment shown in FIG. 8, the depth, 1, of the recesses 112 is now significantly smaller, for instance in a range between 5 μm and 10 μm. Formation of the recesses 112 may be accomplished by plasma dicing or laser grooving. A low-k dielectric layer which may be present in the wafer 100 (not shown in FIG. 8) can be removed by the recessing procedure to further simplify a later cutting-by-blade procedure which will be described below referring to FIG. 13. Such a later mechanical material removal by a blade or other cutting element may work more accurately when the embedded low-k layer is removed before cutting with a blade.

Referring to FIG. 9, electrically conductive interconnect structures 114 are soldered on pads 133, as described above referring to FIG. 3.

Referring to FIG. 10, first temporary holding body 104 is laminated on top of the structure shown in FIG. 9, as illustrated and described referring to FIG. 5.

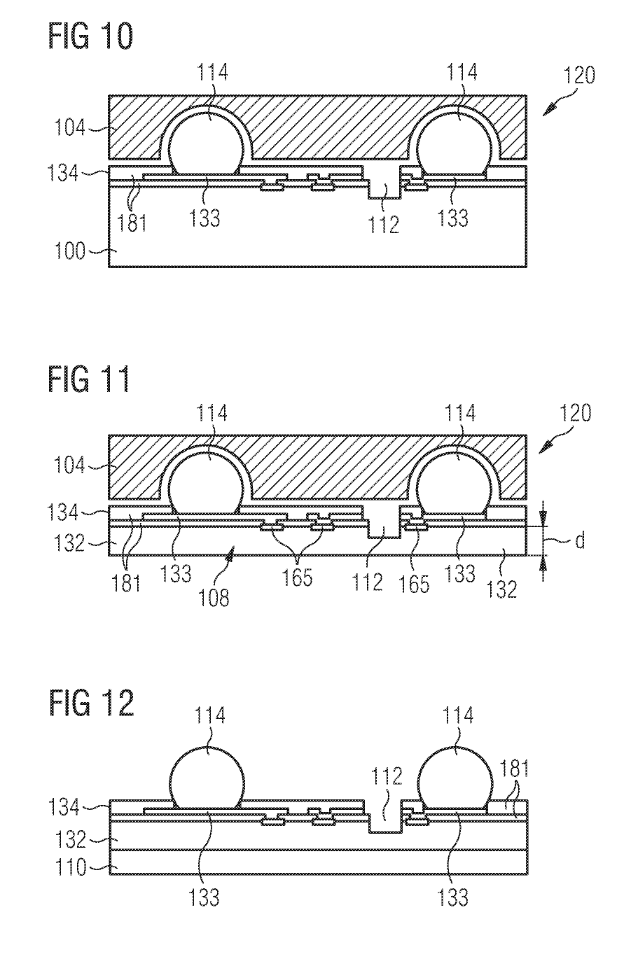

Referring to FIG. 11, material of the recessed wafer 100 is removed from the back side 106 by grinding to thereby thin the wafer 100 to a thickness of d=150 μm. According to the described embodiment, singularization of the wafer 100 into the electronic chips 108 is however not yet completed by the grinding procedure, unlike in the procedure according to FIG. 5.

Laser marking of the electronic chips 108 may be carried out at the stage according to FIG. 12 or at a stage according to subsequently described FIG. 13. Laser marking can be configured as described above referring to FIG. 1 to FIG. 7.

Referring to FIG. 12, second temporary holding body 110 is laminated on a lower main surface of the structure shown in FIG. 11, in a similar way as described above referring to FIG. 6. Thereafter, the first temporary holding body 104 may be removed from the upper main surface of the structure shown in FIG. 11.

Referring to FIG. 13, material of the recessed wafer 100 is then removed from the now exposed front side 102 to thereby singularize the wafer 100 into the plurality of electronic chips 108. This procedure of removing material can be carried out by cutting with a blade (not shown) from the front side 102. As indicated schematically in FIG. 13, this may also remove a small portion of the surface material of the second temporary holding body 110 to ensure that the singularization procedures is reliably completed. This may form an indentation 195 in the second temporary carrier body 110 at the positions of the recesses 112. As an alternative to a blade-cut, separation can also be accomplished by a laser ablation procedure. In the latter alternative, the laser allows substantially any freely selectable chip shape (such as round, triangular, etc.), as with plasma etching.

Referring to FIG. 11 and FIG. 13, the described method therefore singularizes the wafer 100 into the plurality of electronic chips 108 by first thinning the wafer 100 from back side 106 followed by a subsequent removal of material selectively at the recesses 112 from the front side 102.

FIG. 14 shows a cross-sectional view of an electronic device 190 according to an exemplary embodiment. The electronic device 190 is composed of a Chip-Scale-Package, embodied as surface mounted non-encapsulated semiconductor device 130, and a printed circuit board (PCB), as device carrier 192 for carrying the semiconductor device 130. The electric and mechanical coupling between the semiconductor device 130 and the device carrier 192 is accomplished by the electrically conductive interconnect structures 114 interconnecting pads 133 with device carrier pads 155 on an exposed top main surface of the plate like device carrier 192.

It should be noted that the term “comprising” does not exclude other elements or features and the “a” or “a” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, and composition of matter, means, methods and steps described in the specification. Accordingly, the appended claims are intended to include within their scope such processes, machines, manufacture, compositions of matter, means, methods, or steps.

What is claimed is:

1. A manufacturing method, comprising:
forming recesses in a front side of a wafer;
connecting a first temporary holding body to the front side of the recessed wafer;
thereafter thinning the wafer from a back side;
connecting a second temporary holding body to the back side;
thereafter removing the first temporary holding body.

2. The method according to claim 1, wherein the method comprises removing material of the recessed wafer from at least one of the front side and the back side to thereby singularize the wafer into a plurality of electronic chips.

3. The method according to claim 1, wherein the method further comprises attaching electrically conductive interconnect structures on the front side of the wafer before connecting the first temporary holding body to the front side of the recessed wafer and to the electrically conductive interconnect structures.

4. The method according to claim 3, wherein the method further comprises at least one of the group consisting of carrying out a function test of the wafer and writing data in the wafer by applying an electric signal to the electrically conductive interconnect structures before connecting the first temporary holding body to the front side of the recessed wafer and to the electrically conductive interconnect structures.

5. The method according to claim 1, wherein the method further comprises laser processing the back side through the second temporary holding body.

6. A manufacturing method, comprising:
forming recesses in a front side of a wafer;
attaching electrically conductive interconnect structures on the front side of the wafer;
connecting a first temporary holding body to the front side of the recessed wafer and embedding the electrically conductive interconnect structures in the first temporary holding body;
thereafter singularizing the wafer into a plurality of electronic chips.

7. The method according to claim 6, wherein the method comprises singularizing the wafer into the plurality of electronic chips by thinning the wafer from a back side at least up to the recesses.

8. The method according to claim 6, wherein the method comprises singularizing the wafer into the plurality of electronic chips by thinning the wafer from a back side followed by a removal of material at the recesses from the front side.

9. The method according to claim 6, wherein the method further comprises connecting a second temporary holding body to the back side before removing the first temporary holding body.

10. The method according to claim 9, wherein the second temporary holding body is configured as a flexible sheet.

11. The method according to claim 9, wherein the method further comprises individually detaching the electronic chips from the second temporary holding body.

12. A manufacturing method, comprising:
forming a recess in a front side of a wafer;
connecting a temporary holding body to the front side of the recessed wafer;
thereafter thinning the wafer from a back side up to a thickness of less than 300 μm.

13. The method according to claim 12, wherein the method comprises singularizing the wafer into a plurality of electronic chips, in particular by at least one of the group consisting of the thinning and a cutting procedure.

14. The method according to claim 12, wherein the wafer is thinned from an initial thickness (D) of at least 600 μm to a final thickness (d) of not more than 200 μm.

15. The method according to claim 13, wherein the method further comprises re-adhering the electronic chips from the temporary holding body to another temporary holding body on the back side.

16. An intermediate product, comprising:
a plurality of electronic chips;
at least one solder structure on each of the electronic chips;
a common temporary holding body on the electronic chips and the electrically conductive interconnect structures.

17. The intermediate product according to claim 16, wherein the electrically conductive interconnect structures are embedded in the temporary holding body so that the electrically conductive interconnect structures remain attached on the electronic chips upon detaching the temporary holding body from the electronic chips.

18. The intermediate product according to claim 16, wherein the electronic chips have a thickness of not more than 200 μm.

19. The intermediate product according to claim 16, wherein the temporary holding body is configured as a flexible sheet with a plastically deformable or deformed surface portion facing the at least one solder structure and the electronic chips.

20. A non-encapsulated semiconductor device, comprising:
a semiconductor body having a thickness of not more than 200 μm;
at least one solder structure on a front side of the semiconductor body;
a redistribution layer between the semiconductor body and the at least one solder structure.

21. The semiconductor device according to claim 20, configured as a Chip-Scale-Package.

22. An electronic device, comprising:
a device carrier; and
a non-encapsulated semiconductor device according to claim 20 mounted on the device carrier.
